(19) United States
(12) Patent Application Publication
(10) Pub. No.: US 2025/0040222 A1
(43) Pub. Date: Jan. 30, 2025

(54) METHOD OF MANUFACTURING SEMICONDUCTOR DEVICE

(71) Applicant: Renesas Electronics Corporation, Tokyo (JP)

(72) Inventor: Yu NAGAHAMA, Tokyo (JP)

(21) Appl. No.: 18/772,473

(22) Filed: Jul. 15, 2024

(30) Foreign Application Priority Data
Jul. 26, 2023 (JP) 2023-121756

(51) Int. Cl. H01L 29/40; H01L 21/28; H01L 21/311; H01L 29/423

(52) U.S. Cl. CPC H01L 29/407; H01L 21/28167; H01L 21/31111; H01L 29/4236

(57) ABSTRACT

The reliability of the semiconductor device is improved. A field plate electrode FP is formed inside the trench TR via an insulating film IF1. The other part of the field plate electrode FP is selectively retracted toward the bottom of the trench TR so that a part of the field plate electrode FP remains as a lead-out part FPa. A silicon oxide film OX1 is formed on the upper surface of the field plate electrode FP by thermal oxidation. The insulating film IF1 located on the upper surface TS of the semiconductor substrate SUB and the silicon oxide film OX1 are removed, and the insulating film IF1 is retracted so that its upper surface position is lower than the upper surface position of the field plate electrode FP.

### CROSS-REFERENCE TO RELATED APPLICATIONS

The disclosure of Japanese Patent Application No. 2023-121756 filed on Jul. 26, 2023, including the specification, drawings and abstract is incorporated herein by reference in its entirety.

### BACKGROUND

This invention relates to a manufacturing method of semiconductor devices, for example, a method for manufacturing semiconductor devices equipped with gate electrodes and field plate electrodes inside trenches.

In semiconductor devices equipped with semiconductor elements such as Power MOSFETs (Metal Oxide Semiconductor Field Effect Transistors), a trench gate structure with gate electrodes embedded inside trenches is applied. As a type of trench gate structure, a split gate structure is known, where a field plate electrode is formed at the bottom of the trench and a gate electrode is formed at the top of the trench. The field plate electrode is supplied with source potential from the source electrode. By expanding the depletion layer in the drift region through this field plate electrode, it becomes possible to increase the concentration in the drift region, thereby reducing the resistance of the drift region.

For example, a MOSFET with a split gate structure is disclosed in Patent Document 1. The field plate electrode and gate electrode of Patent Document 1 are formed as follows: First, after forming the field plate electrode inside the trench, the upper surface of the field plate electrode is recessed. Next, a conductive film for the gate electrode is deposited on the semiconductor substrate to fill the inside of the trench on the field plate electrode. Then, by performing anisotropic etching on the conductive film, a gate electrode is formed at the top of the trench.

There is a disclosed technique listed below.

### [Patent Document 1] Japanese Unexamined Patent Application Publication No. 2011-199109

### SUMMARY

Inside the trench, a part of the gate electrode may be formed in a protruding manner. When such areas exist, the electric field tends to concentrate, leading to a deterioration in the insulation resistance between the gate electrode and the field plate electrode, and making it easier for leak currents to occur.

Furthermore, the field plate electrode includes a lead-out part for electrical connection to the source electrode. The field plate electrode of the lead-out part is formed not only at the bottom of the trench but also at the top. Anisotropic etching is performed on the conductive film for the gate electrode, but this conductive film may remain as residue on the side of the lead-out part. This can lead to a problem where the insulation resistance between the lead-out part and the semiconductor substrate cannot be maintained.

The main objective of this application is to improve the reliability of semiconductor devices by ensuring the insulation resistance between the gate electrode and the field plate electrode, as well as between the lead-out part and the semiconductor substrate. Other objects and novel features will become apparent from the description of this specification and the accompanying drawings.

The typical ones of the embodiments disclosed in the present application will be briefly described as follow.

The manufacturing method for a semiconductor device according to one embodiment comprises the steps of: (a) providing a semiconductor substrate of a first conductivity type having an upper surface and a lower surface; (b) after (a), forming a trench in the semiconductor substrate so as to reach a predetermined depth from the upper surface of the semiconductor substrate toward the lower surface of the semiconductor substrate; (c) after (b), forming a first insulating film on the upper surface of the semiconductor substrate and inside the trench; (d) after (c), forming a first conductive film on the first insulating film so as to fill the inside of the trench;

(e) after (d), removing the first conductive film located outside the trench to form the first conductive film remaining inside the trench as a field plate electrode; (f) after (e), so that a part of the field plate electrode remains as lead-out part, selectively retracting the other part of the field plate electrode toward the bottom of the trench; (g) after (f), forming a first silicon oxide film on the upper surface of the field plate electrode by thermal oxidation; (h) after (g), removing the first insulating film located on the upper surface of the semiconductor substrate and the first silicon oxide film, and retracting the first insulating film located inside the trench toward the bottom of the trench so that the position of the upper surface of the first insulating film located inside the trench is lower than the position of the upper surface of the field plate electrode in cross-sectional view; (i) after (h), forming a gate insulating film inside the trench on the first insulating film and forming a second insulating film so as to cover the field plate electrode exposed from the first insulating film;
(j) after (i), forming a second conductive film on the gate insulating film, the second insulating film, and the first insulating film to fill the inside of the trench; and (k) after (j), removing the second conductive film located outside the trench to form the second conductive film remaining inside the trench on the field plate electrode as a gate electrode. The second conductive film formed on the first insulating film and the second insulating film in contact with the lead-out part by (j) is removed by (k).

According to one embodiment, the reliability of a semiconductor device can be improved.

### BRIEF DESCRIPTION OF THE DRAWINGS

FIG. 1 is a plan view showing a semiconductor device in the first embodiment.

FIG. 2 is a plan view showing a semiconductor device in the first embodiment.

FIG. 3 is a main portion plan view showing a semiconductor device in the first embodiment.

FIG. 4 is a main portion plan view showing a semiconductor device in the first embodiment.

FIG. 5 is a cross-sectional view showing a semiconductor device in the first embodiment.

FIG. 6 is a cross-sectional view illustrating a manufacturing process of a semiconductor device in the first embodiment.

FIG. 7 is a cross-sectional view illustrating a manufacturing process following FIG. 6.

FIG. 8 is a cross-sectional view illustrating a manufacturing process following FIG. 7.

FIG. 9 is a cross-sectional view illustrating a manufacturing process following FIG. 8.

FIG. 10 is a cross-sectional view illustrating a manufacturing process following FIG. 9.

FIG. 11 is a cross-sectional view illustrating a manufacturing process following FIG. 10.

FIG. 12 is a cross-sectional view illustrating a manufacturing process following FIG. 11.

FIG. 13 is a cross-sectional view illustrating a manufacturing process following FIG. 12.

FIG. 14 is a cross-sectional view illustrating a manufacturing process following FIG. 13.

FIG. 15 is a cross-sectional view illustrating a manufacturing process following FIG. 14.

FIG. 16 is a cross-sectional view illustrating a manufacturing step following FIG. 15.

FIG. 17 is a cross-sectional view illustrating a manufacturing step following FIG. 16.

FIG. 18 is a cross-sectional view illustrating a manufacturing process following FIG. 17.

FIG. 19 is a cross-sectional view illustrating a manufacturing process following FIG. 18.

FIG. 20 is a cross-sectional view illustrating a manufacturing process following FIG. 19.

FIG. 21 is a cross-sectional view illustrating a manufacturing step following FIG. 20.

FIG. 22 is a plan view of a semiconductor device in the first modified example.

FIG. 23 is a cross-sectional view illustrating the manufacturing process of a semiconductor device in the second modified example.

FIG. 24 is a cross-sectional view illustrating the manufacturing process of a semiconductor device in the third modified example.

FIG. 25 is a cross-sectional view illustrating the manufacturing process of a semiconductor device in the fourth modified example.

FIG. 26 is a cross-sectional view showing the manufacturing process of a semiconductor device following FIG. 25.

FIG. 27 is a main part cross-sectional view of a semiconductor device in the examined example 1.

FIG. 28 is a main part cross-sectional view of a semiconductor device in the examined example 1.

FIG. 29 is a main part cross-sectional view of a semiconductor device in the examined example 2.

### DETAILED DESCRIPTION

Hereinafter, embodiments are described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In addition, the X direction, the Y direction, and the Z direction described in the present application intersect each other and are orthogonal to each other. In the present application, the Z direction is described as a vertical direction, a height direction, or a thickness direction of a certain structure. In addition, the expression “plan view” used in the present application means that the plane formed by the X direction and the Y direction is a “plane” and the “plane” is viewed from the Z direction.

### ABOUT EXAMINED EXAMPLES

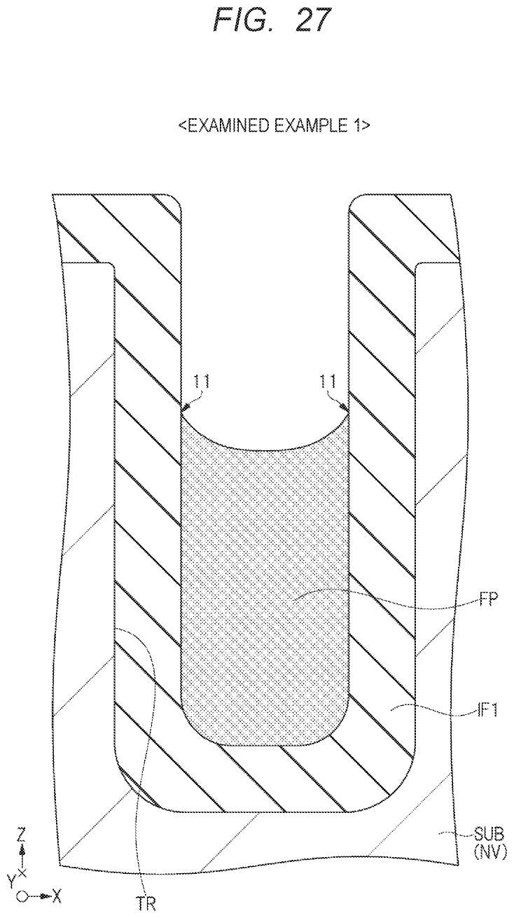

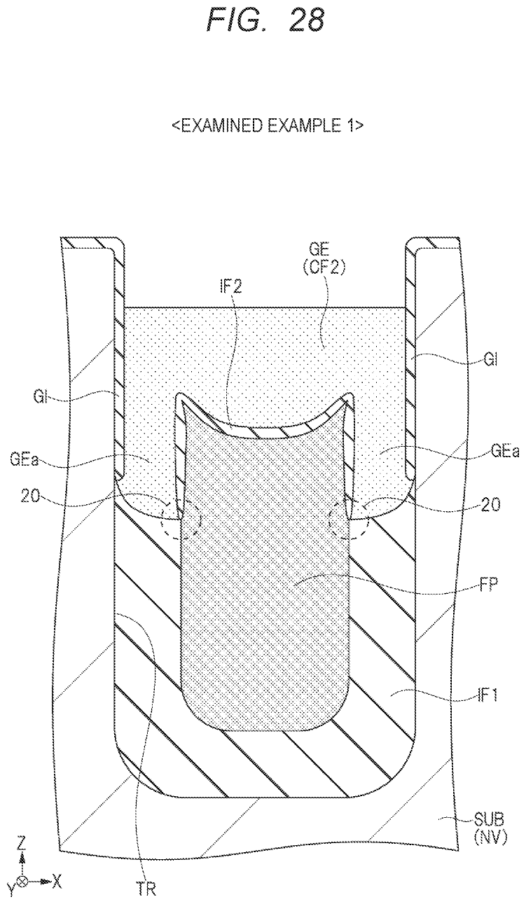

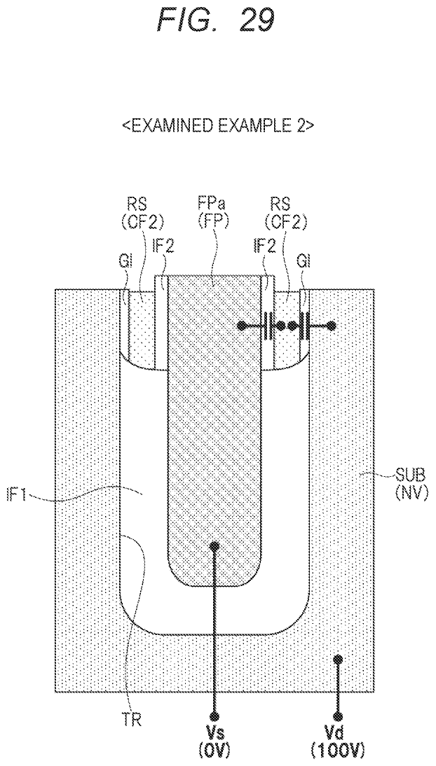

Below, using FIGS. 27 to 29, detailed explanations are given about the issues of semiconductor devices in examined examples 1 and 2, which were investigated by the inventor of the present application based on Patent Document 1 and others. It should be noted that the problems identified from examined examples 1 and 2 are not known in the public domain but are new insights obtained by the inventor of the present application. FIGS. 27 and 28 show the semiconductor device of the examined example 1. FIG. 29 shows the semiconductor device of the examined example 2.

In the examined example 1, as shown in FIG. 27, an insulating film IF1 and a field plate electrode FP are formed inside the trench TR. Next, as shown in FIG. 28, the insulating film IF1 inside the trench TR is recessed by isotropic etching. Then, by performing thermal oxidation, a gate insulating film GI and an insulating film IF2 are formed inside the trench TR.

Next, a conductive film CF2 is deposited to fill the inside of the trench TR, and by performing anisotropic etching on the conductive film CF2, a gate electrode GE is formed on the upper part of the trench TR. A part of the gate electrode GE is also formed as an embedded part GEa between the field plate electrode FP and the semiconductor substrate SUB.

In the examined example 1, the isotropic etching of the insulating film IF1 proceeds from the starting point 11 shown in FIG. 27. Therefore, as shown in FIG. 28, the position of the part of the upper surface of the insulating film IF1 located inside the trench TR that contacts the field plate electrode FP is retracted downward from the position of the part that contacts the side of the semiconductor substrate SUB. That is, the position of the part that contacts the field plate electrode FP is retracted toward the bottom of the trench TR.

Since the embedded part GEa of the gate electrode GE is formed along the shape of the upper surface of the insulating film IF1, the shape of the lower end of the embedded part GEa tends to become protruding. Therefore, the electric field tends to concentrate at the protruding point 20 shown in FIG. 28, causing the insulation withstand voltage between the gate electrode GE and the field plate electrode FP to deteriorate, making it easier for leak currents to occur.

Furthermore, although the insulating film IF2 is formed by thermal oxidation, near the protruding point 20, it is difficult for oxygen gas to reach, making the thickness of the insulating film IF2 locally thinner. Therefore, it becomes even more difficult to ensure the insulation withstand voltage between the gate electrode GE and the field plate electrode FP.

In the examined example 2, as shown in FIG. 29, the field plate electrode FP includes a lead-out part FPa for electrical connection to the source electrode. The field plate electrode FP of the lead-out part FPa is formed not only at the bottom of the trench TR but also at the top of the trench TR.

During the formation of the conductive film CF2, the conductive film CF2 is also deposited in the space surrounded by the insulating films IF1, IF2, and the gate insulating film GI. During the anisotropic etching process to form the gate electrode GE, it is preferable that all the conductive film CF2 present in the above space is removed, but a part of the conductive film CF2 may be left as residue RS.

During the operation of the MOSFET, for example, a source voltage Vs of 0V is supplied to the lead-out part FPa, and a drain voltage Vd of, for example, 100V is supplied to the drift region

NV (semiconductor substrate SUB). Normally, the insulation withstand voltage between the lead-out part FPa and the drift region NV is maintained by the thickness of the insulating film IF1.

However, when an electrically floating residue RS is present, as shown in FIG. 29, the capacitance between the lead-out part FPa and the residue RS, and the capacitance between the residue RS and the drift region NV, form a series capacitance. Since a voltage of 100V is applied to this series capacitance, there is a problem that the insulation withstand voltage between the lead-out part FPa and the drift region NV cannot be maintained.

In particular, when the thickness of the insulating film IF1 is increased to improve the insulation withstand voltage, the time for the isotropic etching process to recess the insulating film IF1 needs to be longer, making it easier for residue RS to form at deeper positions. Also, since the space between the gate insulating film GI and the insulating film IF2 becomes wider, a larger residue RS is more likely to form.

As described above, by mitigating the concentration of the electric field at the protruding point 20, it is possible to ensure the insulation withstand voltage between the gate electrode GE and the field plate electrode FP, and a technology to ensure the insulation withstand voltage between the lead-out part FPa and the drift region NV, by suppressing the generation of a residue RS, is desired.

### FIRST EMBODIMENT

### <Structure of the Semiconductor Device>

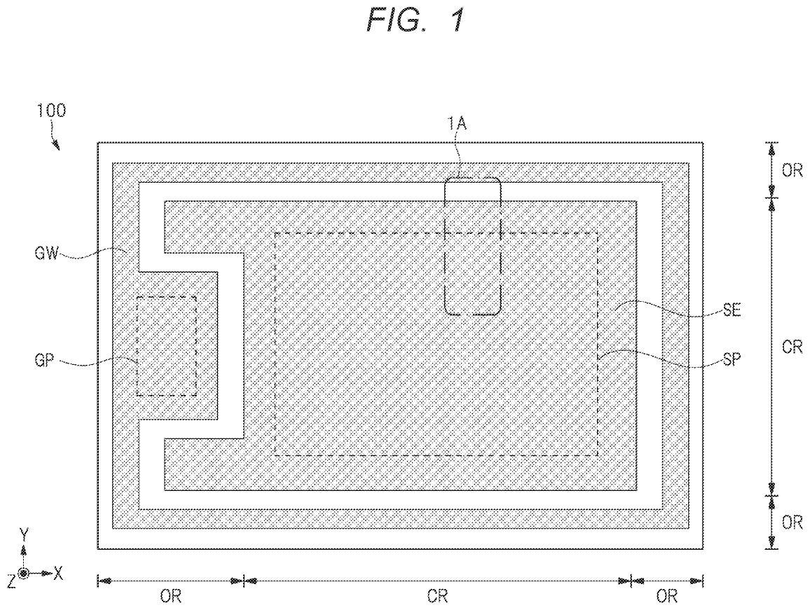

The structure of the semiconductor device 100 in the first embodiment will be described below using FIGS. 1 to 5. The semiconductor device 100 includes a MOSFET with a trench gate structure as a semiconductor element. The MOSFET of the first embodiment e structure equipped with a gate electrode GE and a field plate electrode FP.

The main feature of this application lies in the manufacturing process of forming a silicon oxide film OX1 on the upper surface of the field plate electrode FP, and the manufacturing processes before and after it, which will be described in detail in the ‘Manufacturing Method of Semiconductor Device’ section below.

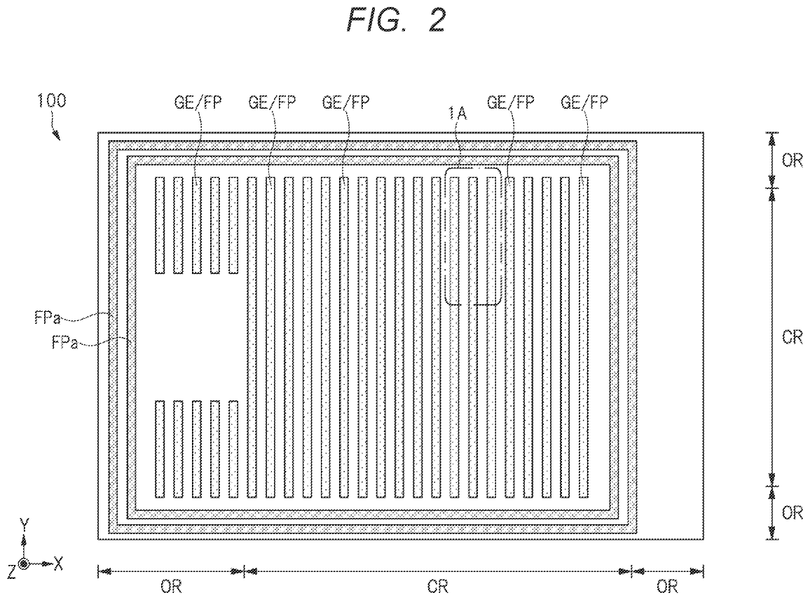

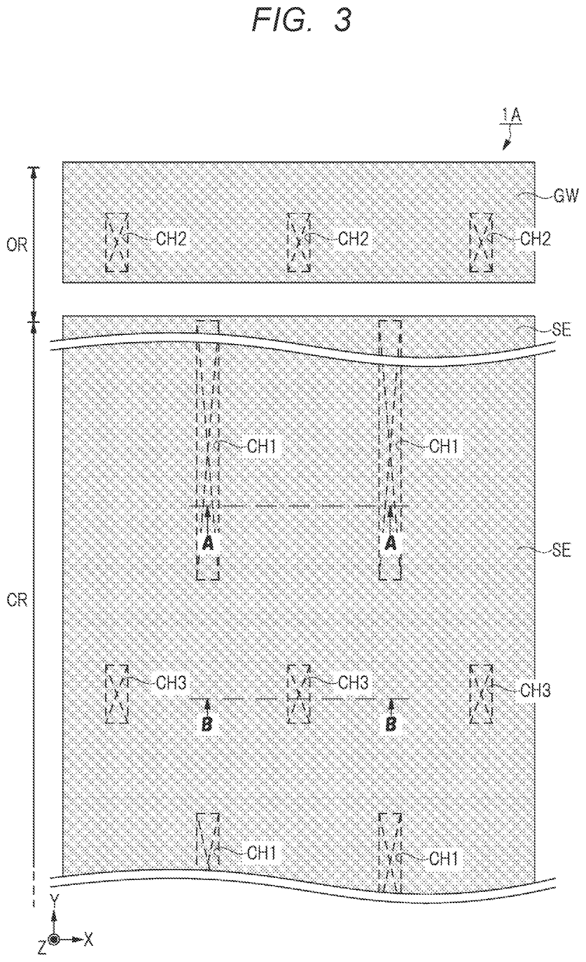

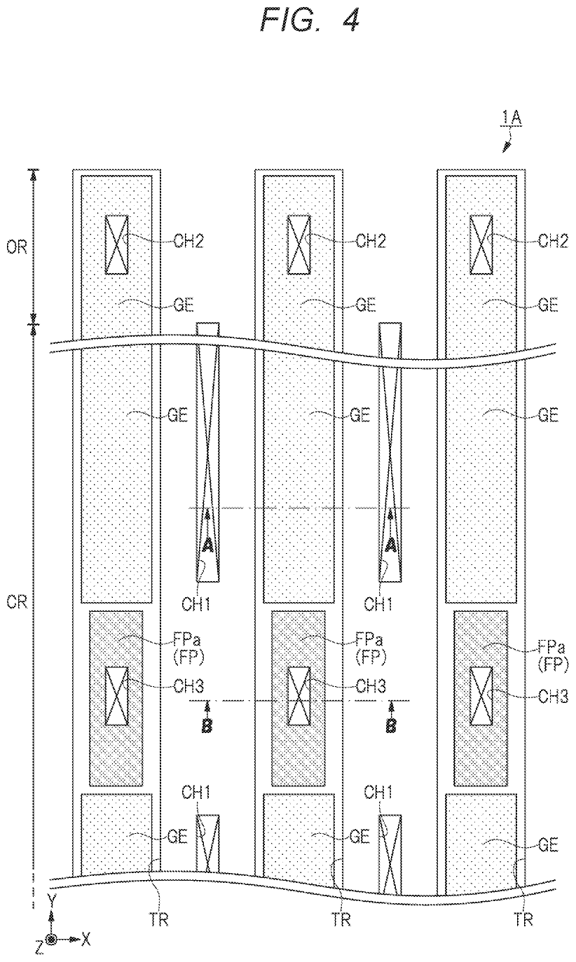

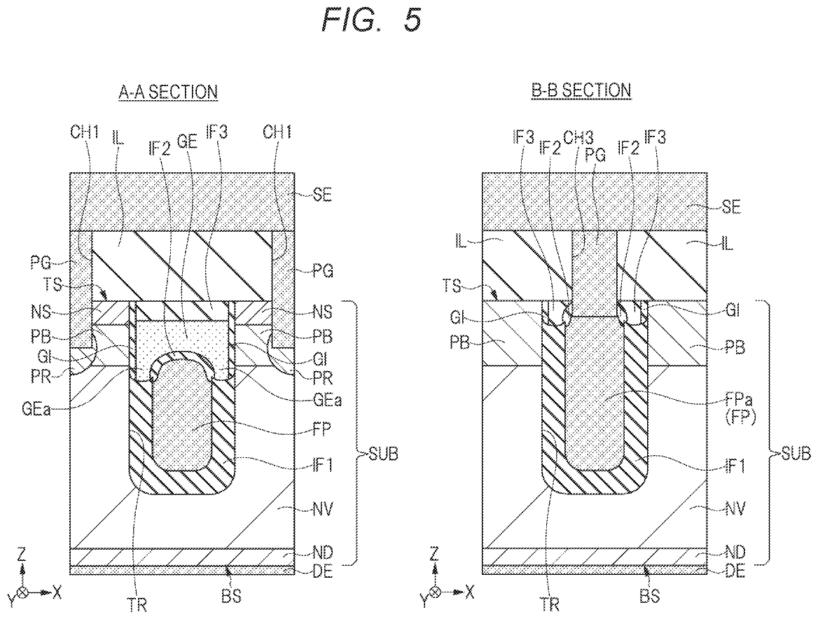

FIGS. 1 and 2 are plan views of the semiconductor chip that is semiconductor device 100. FIGS. 3 and 4 are main part plan views enlarging the area 1A shown in FIGS. 1 and 2. FIGS. 2 and 4 show the structures below FIGS. 1 and 3, mainly the structure of the trench gate formed in the semiconductor substrate SUB. Also, the positions of the holes CH1, CH2, CH3 shown in dashed lines in FIG. 3 coincide with the positions of the holes CH1, CH2, CH3 shown in FIG. 4. FIG. 5 is a cross-sectional view along the lines A-A and B-B shown in FIGS. 3 and 4.

FIG. 1 mainly shows the wiring pattern formed above the semiconductor substrate SUB. The semiconductor device 100 has a cell region CR and a peripheral area OR that surrounds the cell region CR in plan view. In the cell region CR, major semiconductor elements such as multiple MOSFETs are formed. The peripheral area OR is used to connect the gate wiring GW to the gate electrode GE and to function as a termination area, among other things.

As shown in FIGS. 1 and 2, most of the cell region CR is covered with the source electrode SE. In plan view, the gate wiring GW surrounds the source electrode SE. Although not shown here, the source electrode SE and the gate wiring GW are covered with a protective film such as a polyimide film. Some parts of the protective film have openings, and the source electrode SE and gate wiring GW exposed at those openings become the source pad SP and gate pad GP. By connecting external connection members on the source pad SP and the gate pad GP, the semiconductor device 100 is electrically connected to other semiconductor chips, lead frames, or wiring substrates etc. The external connection members are, for example, wires made of aluminum, gold, or copper, or clips made of copper plates.

As shown in FIG. 4, multiple trenches TR are formed in the semiconductor substrate SUB of the cell region CR. The multiple trenches TR are formed in stripes, each extending in the Y direction and adjacent to each other in the X direction.

As also shown in the A-A cross-section of FIG. 5, inside the trench TR, a field plate electrode FP is formed at the bottom of the trench TR, and a gate electrode GE is formed at the top of the trench TR. The field plate electrode FP and the gate electrode GE extend in the Y direction along the trench TR.

As also shown in the B-B cross-section of FIG. 5, a part of the field plate electrode FP in the cell region CR forms a lead-out part FPa. The field plate electrode FP forming the lead-out part FPa is formed not only at the bottom but also at the top of the trench TR inside the trench TR.

As shown in FIG. 2, multiple trenches TR formed in the outer peripheral region OR extend in the Y and X directions, surrounding the cell region CR in plan view. Inside the trenches TR of the outer peripheral region OR, a field plate electrode FP that constitutes the lead-out part FPa is formed.

In the cell region CR, a hole CH3 is formed on the lead-out part FPa. The lead-out part FPa is electrically connected to the source electrode SE through the hole CH3. Also, in the cell region CR, a hole CH1 is formed on the body area PB and the source area NS to be described later. The body area PB and the source area NS are electrically connected to the source electrode SE through the hole CH1. In the outer peripheral region OR, a hole CH2 is formed on the gate electrode GE. The gate electrode GE is electrically connected to the gate wiring GW through the hole CH2.

The cross-sectional structure of the semiconductor device 100 will be described below using FIG. 5.

As shown in FIG. 5, the semiconductor device 100 includes an n-type semiconductor substrate SUB with an upper surface TS and a lower surface BS. The semiconductor substrate SUB is made of n-type silicon. The semiconductor substrate SUB has a low concentration n-type drift region NV. In the first embodiment, the n-type semiconductor substrate SUB itself constitutes the drift region NV. Furthermore, the semiconductor substrate SUB may be a laminate of an n-type silicon substrate and an n-type semiconductor layer grown on the n-type silicon substrate with introducing phosphorus (P) through epitaxial growth. In that case, the low concentration n-type semiconductor layer constitutes the drift region NV, and the high concentration n-type silicon substrate constitutes the drain region ND.

In the semiconductor substrate SUB, an n-type drain region ND is formed to reach a predetermined depth from the lower surface BS of the semiconductor substrate SUB toward the upper surface TS. The drain region ND has a higher impurity concentration than the drift region NV. A drain electrode DE is formed on the lower surface BS of the semiconductor substrate SUB. The drain electrode DE consists of a single layer of metal film such as aluminum, titanium, nickel, gold, or silver film, or a laminated film made by appropriately laminating these metal films. The drain region ND and the drain electrode DE are formed across the cell region CR and the outer peripheral region OR. A drain potential is supplied to the semiconductor substrate SUB (drain region ND, drift region NV) from the drain electrode DE.

In the semiconductor substrate SUB, multiple trenches TR are formed to reach a predetermined depth from the upper surface TS of the semiconductor substrate SUB toward the lower surface BS. The depth of each trench TR is, for example, equal to or more than 5 μm (5 micrometers) and equal to or less than 7 μm (7 micrometers).

As shown in the A-A cross-section of FIG. 5, inside the trench TR, a field plate electrode FP is formed at the bottom of the trench TR through an insulating film IF1. The position of the upper surface of the insulating film IF1 is lower than the position of the upper surface of the field plate electrode FP.

The gate insulating film GI is formed inside the trench TR on the insulating film IF1. The insulating film IF2 is formed to cover the field plate electrode FP exposed from the insulating film IF1. A gate electrode GE is formed on the field plate electrode FP through the insulating film IF2. The field plate electrode FP and the gate electrode GE are each made of polycrystalline silicon films into which n-type impurities have been introduced, for example. Furthermore, the impurity concentration of this polycrystalline silicon film is higher than the impurity concentration of the semiconductor substrate SUB (drift region NV).

Also, a part of the gate electrode GE is formed in the space between the field plate electrode FP and the semiconductor substrate SUB, and is surrounded by the insulating films IF1, IF2, and the gate insulating film GI. Such a part of the gate electrode GE is referred to as the embedded part GEa.

The insulating film IF1 is formed between the semiconductor substrate SUB and the field plate electrode FP. The insulating film IF2 is formed between the gate electrode GE and the field plate electrode FP. The gate insulating film GI is formed between the semiconductor substrate SUB and the gate electrode GE. Through these films, the semiconductor substrate SUB, the gate electrode GE, and the field plate electrode FP are electrically insulated from each other.

Furthermore, although the insulating film IF3 is formed on the gate electrode GE, the insulating film IF3 is primarily used as a protective film to protect the cell region CR when forming other semiconductor elements like resistive elements in areas different from the cell region CR. Therefore, the insulating film IF3 does not need to be formed if there is no need to form other semiconductor elements.

The insulating films IF1, IF2, IF3, and the gate insulating film GI are made of, for example, a silicon oxide film. The thickness of the insulating film IF1 is greater than the thickness of each of the insulating film IF2 and the gate insulating film GI, and is, for example, equal to or more than 400 nm and equal to or less than 600 nm. The thickness of each of the insulating film IF2 and the gate insulating film GI is, for example, equal to or more than 50 nm and equal to or less than 70 nm. Note that these thicknesses are the thicknesses inside the trench TR and in the X direction.

In the semiconductor substrate SUB, a p-type body region PB is formed to a certain depth from the upper surface TS of the semiconductor substrate SUB toward the lower surface BS of the semiconductor substrate SUB. The depth of the body region PB from the upper surface TS of the semiconductor substrate SUB is shallower than the depth of the trench TR from the upper surface TS of the semiconductor substrate SUB. Within the body region PB, an n-type source region NS is formed. The source region NS has a higher impurity concentration than the drift region NV.

On the upper surface TS of the semiconductor substrate SUB, an interlayer insulating film IL is formed to cover the trench TR. The interlayer insulating film IL is made of, for example, a silicon oxide film. The thickness of the interlayer insulating film IL is, for example, equal to or more than 700 nm and equal to or less than 900 nm.

In the interlayer insulating film IL, a hole CH1 is formed that extends through the interlayer insulating film IL and the source region NS, and reaches the body region PB. At the bottom of the hole CH1, a high concentration diffusion region PR is formed in the body region PB. The high concentration diffusion region PR has a higher impurity concentration than the body region PB. The high concentration diffusion region PR is mainly provided to reduce the contact resistance with the plug PG and to prevent latch-up.

On the interlayer insulating film IL, a source electrode SE is formed. The source electrode SE is electrically connected to the source region NS, the body region PB, and the high concentration diffusion region PR through the hole CH1, supplying the source potential to these impurity regions.

As shown in the B-B cross-section of FIG. 5, a part of the field plate electrode FP constitutes the lead-out part FPa of the field plate electrode FP. The position of the upper surface of the insulating film IF1 in contact with the lead-out part FPa is higher than the position of the upper surface of the insulating film IF1 in contact with the field plate electrode FP other than the lead-out part FPa.

The insulating film IF2 is formed to cover the lead-out part FPa exposed from the insulating film IF1. An insulating film IF3 is formed on the insulating film IF1, but as mentioned above, it is not necessary to form the insulating film IF3. Also, a body region PB is formed in the semiconductor substrate SUB adjacent to the lead-out part FPa, but a source region NS is not formed within this body region PB.

In the interlayer insulating film IL, a hole CH3 is formed that extends through the interlayer insulating film IL, the insulating film IF3, and the insulating film IF2, and reaches the lead-out part FPa. The source electrode SE is electrically connected to the lead-out part FPa through the hole CH3 and supplies a source potential to the field plate electrode FP.

Although not shown here, in the interlayer insulating film IL, a hole CH2 is formed that extends through the interlayer insulating film IL and the insulating film IF3, and reaches the gate electrode GE. The gate wiring GW is electrically connected to the gate electrode GE through the hole CH2 and supplies a gate potential to the gate electrode GE.

Inside each of the holes CH1, CH2, and CH3, a plug PG is embedded. The plug PG consists of, for example, a first barrier metal film and a first conductive film formed on the first barrier metal film. The first barrier metal film consists of, for example, a laminated film of titanium film and titanium nitride film. The first conductive film is, for example, a tungsten film.

The source electrode SE and the gate wiring GW consist of, for example, a second barrier metal film and a second conductive film formed on the second barrier metal film. The second barrier metal film is, for example, a titanium tungsten film. The second conductive film is, for example, an aluminum alloy film to which copper or silicon has been added.

### <Manufacturing Method of Semiconductor Device>

The following describes each manufacturing process included in the manufacturing method of the semiconductor device 100, using

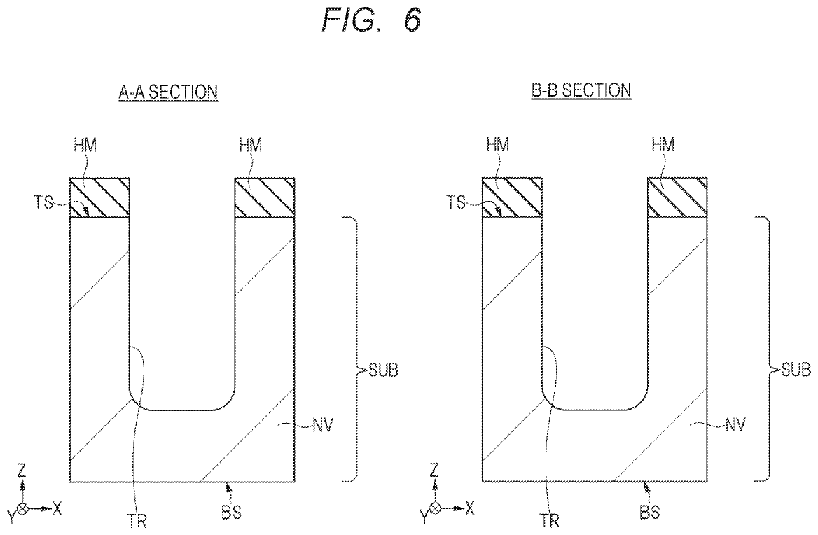

FIGS. 6 to 21.

First, an n-type semiconductor substrate SUB with an upper surface TS and a lower surface BS is prepared. As mentioned above, the semiconductor substrate SUB may be a laminate of an n-type silicon substrate and an n-type semiconductor layer formed on the silicon substrate by epitaxial growth.

Next, an oxide silicon film is formed on the semiconductor substrate SUB, for example, by CVD (Chemical Vapor Deposition) method. Then, by patterning the oxide silicon film using photolithography technology and anisotropic etching process, a hard mask HM is formed. Then, by performing anisotropic etching process using the hard mask HM as a mask, a trench TR is formed in the semiconductor substrate SUB to reach a predetermined depth from the upper surface TS of the semiconductor substrate SUB to the lower surface BS, as shown in FIG. 6. Afterward, the hard mask HM is removed by wet etching process using a solution containing hydrofluoric acid, for example.

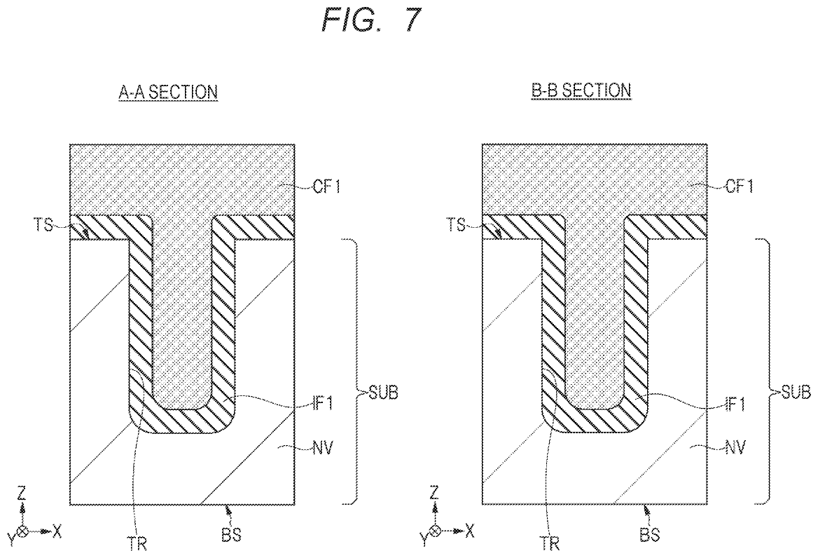

Next, as shown in FIG. 7, an insulating film IF1 is formed inside the trench TR and on the upper surface TS of the semiconductor substrate SUB. The insulating film IF1 is, for example, an oxide silicon film formed by thermal oxidation process. The thickness of the insulating film IF1 on the upper surface TS of the semiconductor substrate SUB is, for example, equal to or more than 400 nm and equal to or less than 600 nm. Furthermore, the insulating film IF1 may be a laminated film consisting of a first silicon oxide film formed by thermal oxidation treatment, and a second silicon oxide film formed on the first silicon oxide film by film formation using the CVD method.

Next, a conductive film CF1 is formed on the insulating film IF1 by film formation using the CVD method, for example, so as to fill the inside of the trench TR. The conductive film CF1 is, for example, an n-type polycrystalline silicon film. Furthermore, the impurity concentration of this polycrystalline silicon film is higher than the impurity concentration of the semiconductor substrate SUB (drift region NV). To satisfactorily embed the conductive film CF1 inside the trench TR, the formation of the conductive film CF1 may be divided into multiple times, such as the formation of the first polycrystalline silicon film and the formation of the second polycrystalline silicon film.

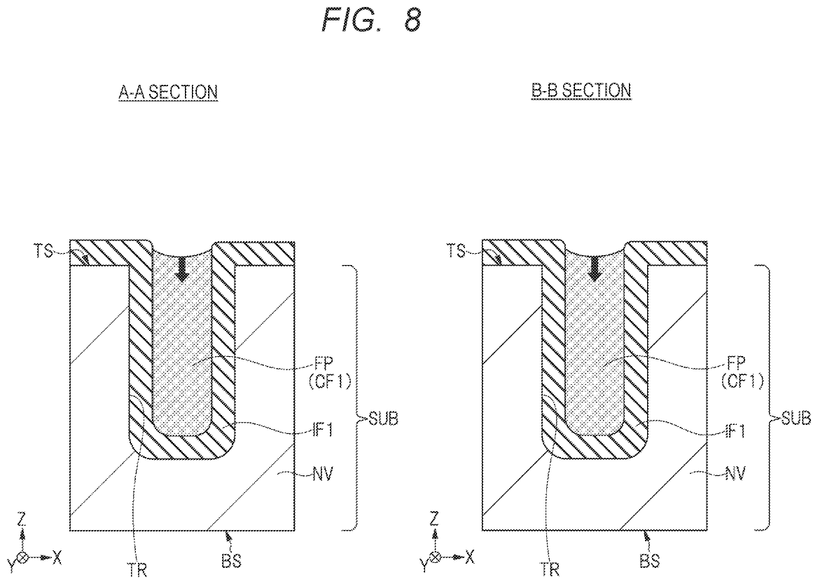

Next, as shown in FIG. 8, by removing the conductive film CF1 located outside the trench TR, the conductive film CF1 remaining inside the trench TR is formed as a field plate electrode FP.

Specifically, first, the conductive film CF1 formed outside the trench TR is removed by polishing using, for example, the CMP (Chemical Mechanical Polishing) method. Then, by performing anisotropic etching using, for example, SF6 gas, the position of the upper surface of the conductive film CF1 inside the trench TR is retracted toward the bottom of the trench TR (arrow in FIG. 8). This forms the conductive film CF1 remaining inside the trench TR as a field plate electrode FP.

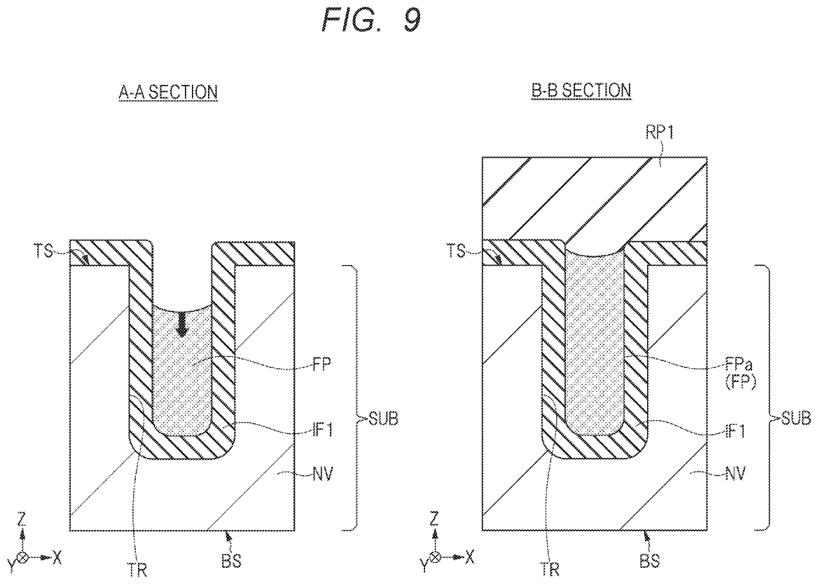

Next, as shown in FIG. 9, another part of the field plate electrode FP is selectively retracted so that a part of the field plate electrode remains as the lead-out part FPa.

Specifically, first, as shown in the B-B cross-section of FIG. 9, a resist pattern RP1 is formed to selectively cover a part of the field plate electrode FP that will become the lead-out part FPa. Then, using the resist pattern RP1 as a mask, other parts of the field plate electrode FP that will not become the lead-out part FPa are removed by performing anisotropic etching using, for example, SF₆ gas. That is, as shown in the A-A cross-section of FIG. 9, other parts of the field plate electrode FP that will not become the lead-out part FPa are selectively retracted toward the bottom of the trench TR (arrow in FIG. 9). The part of the field plate electrode FP that was not retracted becomes the lead-out part FPa. Afterward, the resist pattern RP1 is removed by ashing.

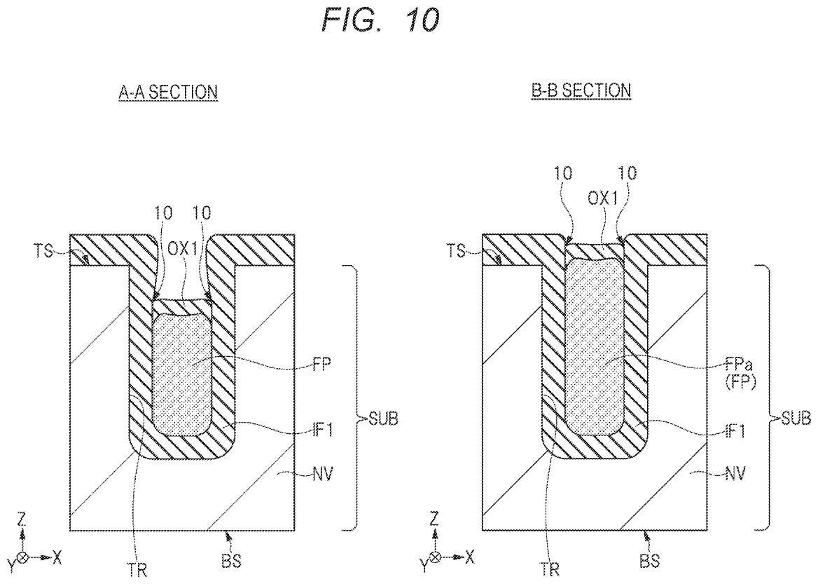

Next, as shown in FIG. 10, a silicon oxide film OX1 is formed on the upper surface of the field plate electrode FP by thermal oxidation treatment. This thermal oxidation treatment is a wet oxidation process, performed using water vapor under a condition of at least 850 degrees Celsius but not exceeding 950degrees Celsius. Furthermore, this thermal oxidation treatment increases the thickness of the insulating film IF1 formed above the field plate electrode FP.

This thermal oxidation treatment rounds the upper part of the field plate electrode FP. Also, in the X direction, the width of the upper part of the field plate electrode FP becomes narrower by the thickness of the silicon oxide film OX1.

The upper part of the field plate electrode FP includes the upper surface of the field plate electrode FP and a part of the side surface of the field plate electrode FP that is contiguous with this upper surface. In other words, the upper part of the field plate electrode FP is the area of the field plate electrode FP that is exposed from the insulating film IF1.

Furthermore, FIG. 10 shows the starting point 10 for the isotropic etching process performed on the insulating film IF1 and the silicon oxide film OX1. It should be noted that the etching in the isotropic etching process progresses over the entire surfaces of the insulating film IF1 and the silicon oxide film OX1, but the starting point 10 described here refers to a position that particularly influences the shape of the insulating film IF1 at the location which ultimately contacts the field plate electrode FP.

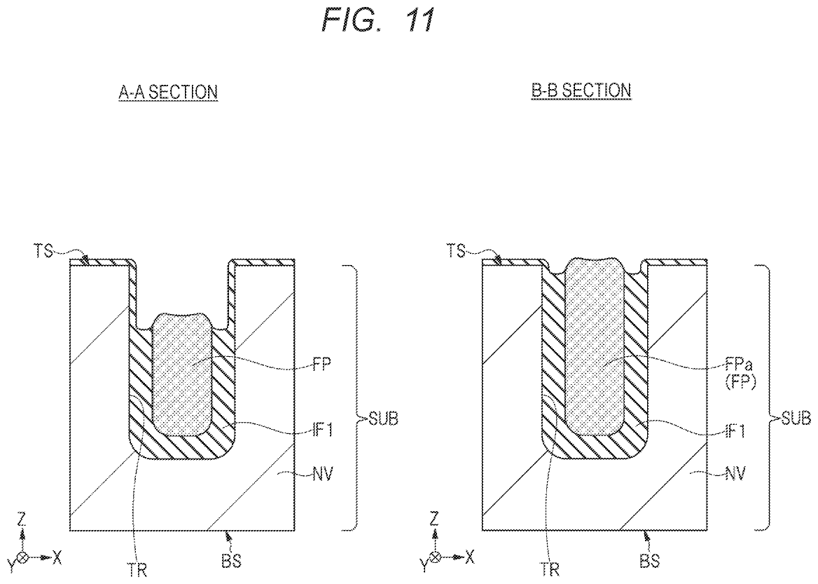

After the manufacturing process of FIG. 10, by performing isotropic etching, as shown in FIG. 11, the silicon oxide film OX1 is removed, the thickness of the insulating film IF1 is reduced, and the upper part of the field plate electrode FP is exposed from the insulating film IF1. The isotropic etching process is, for example, a wet etching process using a solution containing hydrofluoric acid. At this point, the insulating film IF1 on the upper surface TS of the semiconductor substrate SUB and inside the trench TR is not completely removed.

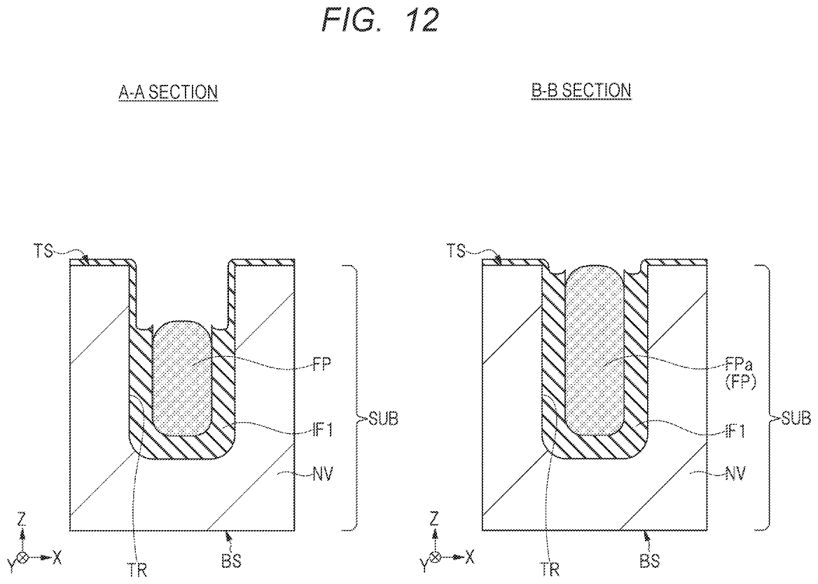

Next, isotropic etching is performed on the upper part of the field plate electrode FP that is exposed from the insulating film IF1. This isotropic etching process is a chemical dry etching process using CF4 gas. As a result, as shown in FIG. 12, the upper part of the field plate electrode FP is further rounded.

Furthermore, during this isotropic etching process, the thinned insulating film IF1 on the upper surface TS of the semiconductor substrate SUB and inside the trench TR acts as an etching stopper, so the semiconductor substrate SUB is not exposed to the isotropic etching process.

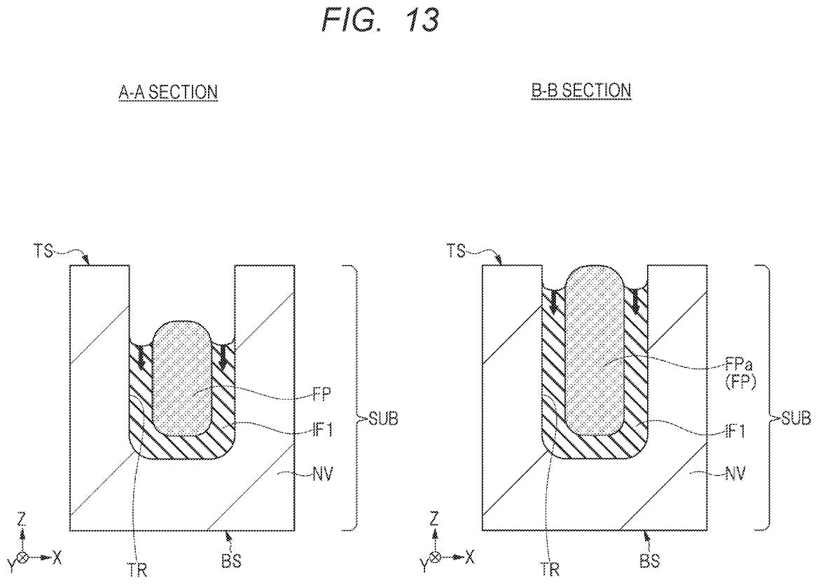

Next, isotropic etching is performed on the insulating film IF1 using a solution containing hydrofluoric acid. As a result, as shown in FIG. 13, the insulating film IF1 located on the upper surface TS of the semiconductor substrate SUB is removed, and the insulating film IF1 located inside the trench TR is retracted toward the bottom of the trench TR (arrow in FIG. 13). In the first embodiment, as shown in FIG. 13, the insulating film IF1 located inside the trench TR is retracted toward the bottom of the trench TR so that the upper surface position of the insulating film IF1 located inside the trench TR is lower than the upper surface position of the field plate electrode FP in cross-sectional view.

At this point, the position of the upper surface of the insulating film IF1 that is in contact with the field plate electrode FP other than the lead-out part FPa is lower than the position of the upper surface of the insulating film IF1 that is in contact with the lead-out part FPa.

It should be noted that the manufacturing processes of FIGS. 11 and 12 are not essential and may be omitted. That is, after the manufacturing process of FIG. 10, by performing the manufacturing process of FIG. 13, the insulating film IF1 located on the upper surface TS of the semiconductor substrate SUB and the silicon oxide film OX1 may be removed, and the insulating film IF1 located inside the trench TR may be retracted toward the bottom of the trench TR.

However, by performing the manufacturing processes shown in FIGS. 11 and 12, although the number of steps increases, the upper part of the field plate electrode FP is further rounded, making it easier to uniform the electric field between the gate electrode GE and the field plate electrode FP.

Additionally, if the thermal oxidation process shown in FIG. 10 is a wet oxidation process, it is easier to ensure the thickness of the silicon oxide film OX1, but variations in the thickness of the silicon oxide film OX1 may occur. In that case, after removing the silicon oxide film OX1, the surface of the field plate electrode FP becomes rough. By performing the isotropic etching process shown in FIG. 12, it is possible to further round the upper part of the field plate electrode FP and smooth the surface of the field plate electrode FP.

It is also possible to perform the thermal oxidation process shown in FIG. 10 as a dry oxidation process. This dry oxidation process is performed, for example, under a condition of equal to or more than 1000 degrees Celsius and equal to or less than 1200 degrees Celsius using oxygen gas. In the dry oxidation process, the uniformity of the thickness of the silicon oxide film OX1 is higher compared to the wet oxidation process. Therefore, after removing the silicon oxide film OX1, it is less likely for the surface of the field plate electrode FP to become rough. However, in the dry oxidation process, since the effect of accelerated oxidation is less, it is difficult to make the thickness of the silicon oxide e film OX1 thicker compared to the wet oxidation process. Therefore, from the perspectives of raising the position of the starting point 10, rounding the upper part of the field plate electrode FP, and narrowing the width of the upper part of the field plate electrode FP, the wet oxidation process is superior to the dry oxidation process.

The isotropic etching process shown in FIG. 11 proceeds from the starting point 10 shown in FIG. 10. Or, if the manufacturing processes shown in FIGS. 11 and 12 are omitted, the isotropic etching process shown in FIG. 13 proceeds from the starting point 10 shown in FIG. 10. In any case, at the end of the isotropic etching process shown in FIG. 13, as shown in FIG. 13, the upper surface of the insulating film IF1 forms a curve which rises as it approaches the semiconductor substrate SUB and rises as it approaches the field plate electrode FP.

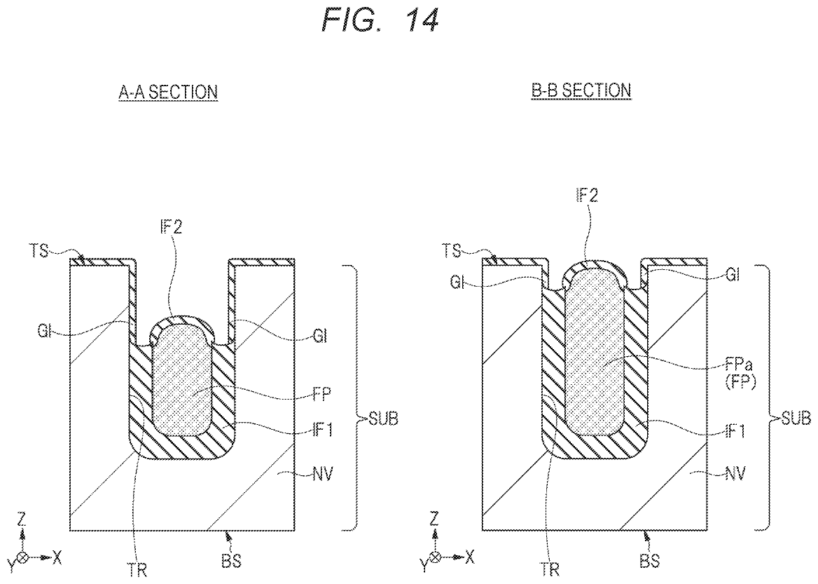

Next, as shown in FIG. 14, a gate insulating film GI is formed on the upper surface TS of the semiconductor substrate SUB and inside the trench TR located on the insulating film IF1, and an insulating film IF2 is formed to cover the field plate electrode FP exposed from the insulating film IF1.

The gate insulating film GI and the insulating film IF2 are formed by a thermal oxidation process such as dry oxidation. This dry oxidation process is performed, for example, under a condition of equal to or more than 1000 degrees Celsius and equal to or less than 1200 degrees Celsius using oxygen gas. Furthermore, the gate insulating film GI and the insulating film IF2 may be a laminated film of the third silicon oxide film formed by the dry oxidation process and the fourth silicon oxide film formed on the third silicon oxide film by a film formation process using CVD.

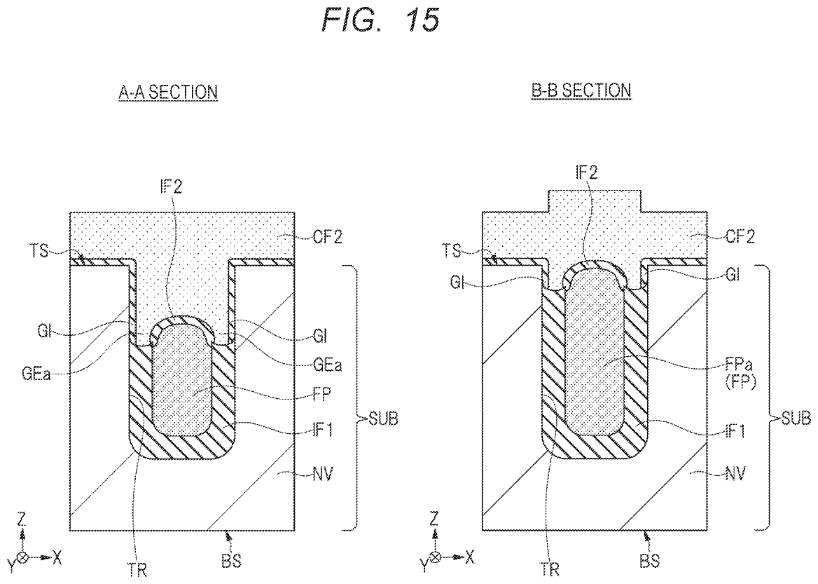

Next, as shown in FIG. 15, a conductive film CF2 is formed on the gate insulating film GI, the insulating film IF2, and the insulating film IF1, for example, by a film formation process using CVD, so as to fill the inside of the trench TR. The conductive film CF2 is, for example, an n-type polycrystalline silicon film. Furthermore, the impurity concentration of this polycrystalline silicon film is higher than the impurity concentration of the semiconductor substrate SUB (drift region NV).

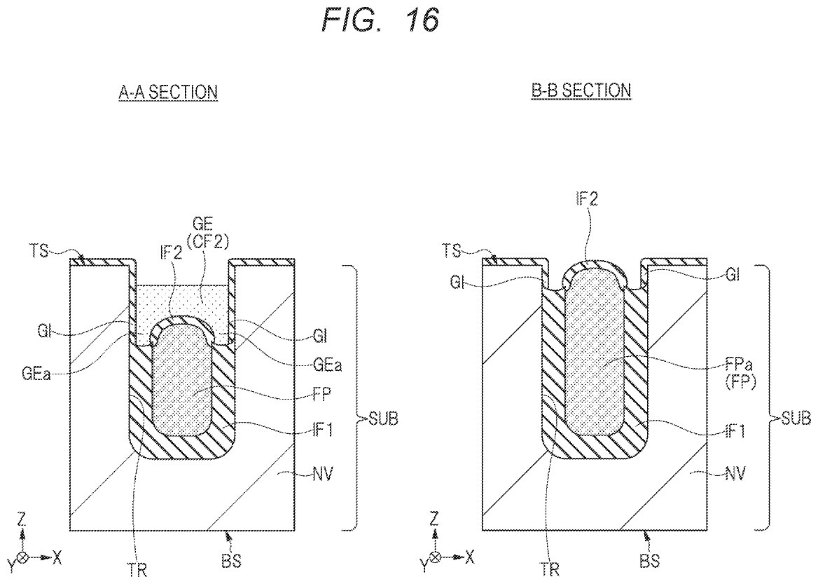

Next, a polishing process using the CMP method is performed on the conductive film CF2. As a result, the thickness of the conductive film CF2 is reduced, and the upper surface of the conductive film CF2 is flattened. Next, by performing anisotropic etching on the conductive film CF2, the conductive film CF2 located outside the trench TR is removed. As a result, as shown in FIG. 16, the conductive film CF2 remaining inside the trench TR on the field plate electrode FP is formed as the gate electrode GE.

Furthermore, as shown in the A-A cross-section of FIG. 16, a part of the gate electrode GE is formed as an embedded portion GEa in the space surrounded by the insulating films IF1, IF2, and the gate insulating film GI, between the field plate electrode FP and the semiconductor substrate SUB.

Note that, to completely remove the conductive film CF2 outside the trench TR, the anisotropic etching process is performed with over-etching. Therefore, as shown in the A-A cross-section of FIG. 16, the position of the upper surface of the gate electrode GE becomes lower than the position of the upper surface TS of the semiconductor substrate SUB. Also, as shown in the B-B cross-section of FIG. 16, the conductive film CF2 formed on the insulating films IF1 and IF2, which are in contact with the lead-out part FPa, is removed by this anisotropic etching process.

### <Main Features of the First Embodiment>

Below, the main features of the first embodiment are described while comparing with the examined example 1 and the examined example 2.

As mentioned above, in the examined example 1, the isotropic etching process on the insulating film IF1 proceeds from the starting point 11 shown in FIG. 27. Therefore, as shown in FIG. 28, the position of the part of the upper surface of the insulating film IF1 located inside the trench TR, which is in contact with the field plate electrode FP, is recessed downward compared to the position of the part in contact with the side of the semiconductor substrate SUB. Subsequently, when the gate electrode GE is formed from the conductive film CF2, the shape of the lower end of the embedded portion GEa tends to become protruding, making it easier for the electric field to concentrate at the protrusion point 20 shown in FIG. 28. Furthermore, near the protrusion point 20, it becomes difficult for oxygen gas to reach, making the thickness of the insulating film IF2 locally thinner. Therefore, in the examined example 1, there was a problem in securing the insulation withstand voltage between the gate electrode GE and the field plate electrode FP.

In the first embodiment, a silicon oxide film OX1 is formed on the upper surface of the field plate electrode FP by performing the thermal oxidation process shown in FIG. 10. Therefore, the isotropic etching process performed on the insulating film IF1 and the silicon oxide film OX1 proceeds from the starting point 10, which is higher than the starting point 11 of the examined example 1.

As a result, at the end of the isotropic etching process shown in FIG. 13, the upper surface of the insulating film IF1 forms a curved surface that rises as it approaches the semiconductor substrate SUB and also rises as it approaches the field plate electrode FP in the X direction shown in FIG. 13. Note that, when a film formation process using the CVD method is applied for forming the insulating film IF1, the etching rate during the isotropic etching process is faster for the CVD film than for the thermal oxidation treatment film, making it even easier to form the aforementioned curved surface. Subsequently, as shown in the A-A cross-section of FIG. 16, even when the gate electrode GE is formed from the conductive film CF2, the shape of the lower end of the embedded portion GEa does not become protruding. Therefore, the problem of electric fields tending to concentrate at the protrusion site 20 (near the insulating film IF1) in the examined example 1 is resolved.

Furthermore, even if the thickness of the insulating film IF2 is thin near the insulating film IF1, the thickness can be supplemented by the insulating film IF1. Therefore, it is possible to ensure the insulation withstand voltage between the gate electrode GE and the field plate electrode FP and improve the reliability of the semiconductor device 100.

Also, by performing the thermal oxidation process of FIG. 10, the upper part of the field plate electrode FP is rounded. In FIG. 12, by performing isotropic etching on the upper part of the field plate electrode FP, the upper part of the field plate electrode FP is further rounded. Therefore, it is less likely for electric fields to concentrate between the gate electrode GE and the field plate electrode FP. That is, since it is easier to uniform the electric field between the gate electrode GE and the field plate electrode FP, the insulation withstand voltage between them can be further ensured.

In the examined example 2, as shown in FIG. 29, during the formation of the conductive film CF2 around the lead-out part FPa, the conductive film CF2 is also deposited in the space surrounded by the insulating film IF1, the insulating film IF2, and the gate insulating film GI. There was a problem that a part of the conductive film CF2 present in this space could not be removed by anisotropic etching, leaving a residue RS.

In the first embodiment, the aspect ratio of the aforementioned space is lower than in the examined example 2.Therefore, as shown in the B-B cross-section of FIG. 16, when anisotropic etching is performed on the conductive film CF2, the conductive film CF2 formed on the insulating film IF1 and the insulating film IF2 in contact with the lead-out part FPa can be completely removed.

The reason for the low aspect ratio of the aforementioned space is, firstly, that the width of the upper part of the lead-out part FPa becomes narrower due to the thermal oxidation process of FIG. 10. Next, by performing the thermal oxidation process of FIG. 10 and the isotropic etching process of FIG. 12, the upper part of the lead-out part FPa is rounded. These processes result in a wider opening of the aforementioned space.

Next, during the isotropic etching process, since the starting point 10 of the first embodiment is at a high position, the depth of the aforementioned space becomes shallower compared to the examined example 2. Next, in the examined example 2, as shown in FIG. 29, since the upper surface of the insulating film IF1 in contact with the lead-out part FPa is recessed downwards, the shape of the lower end of the residue RS tends to be protruding, forming the residue RS deeper. In the first embodiment, as shown in the B-B cross-section from FIG. 13 to FIG. 16, the upper surface of the insulating film IF1 rises as it approaches the lead-out part FPa. Therefore, since there is no conductive film CF2 that becomes protruding, it is easier to remove the conductive film CF2 by anisotropic etching.

Thus, in the first embodiment, since the generation of residue RS can be suppressed, the insulation withstand voltage between the lead-out part FPa and the drift region NV (semiconductor substrate SUB) can be maintained, and the reliability of the semiconductor device 100 can be improved.

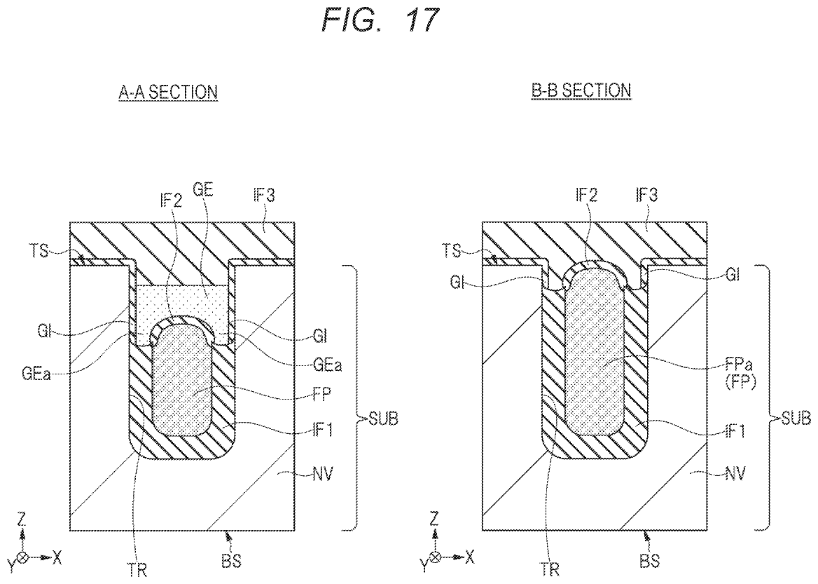

After the manufacturing process of FIG. 16, as shown in FIG. 17, an insulating film IF3 is formed on the gate insulating film GI, the gate electrode GE, the insulating film IF2, and the insulating film IF1, for example, by a film formation process using the CVD method, so as to cover the trench TR.

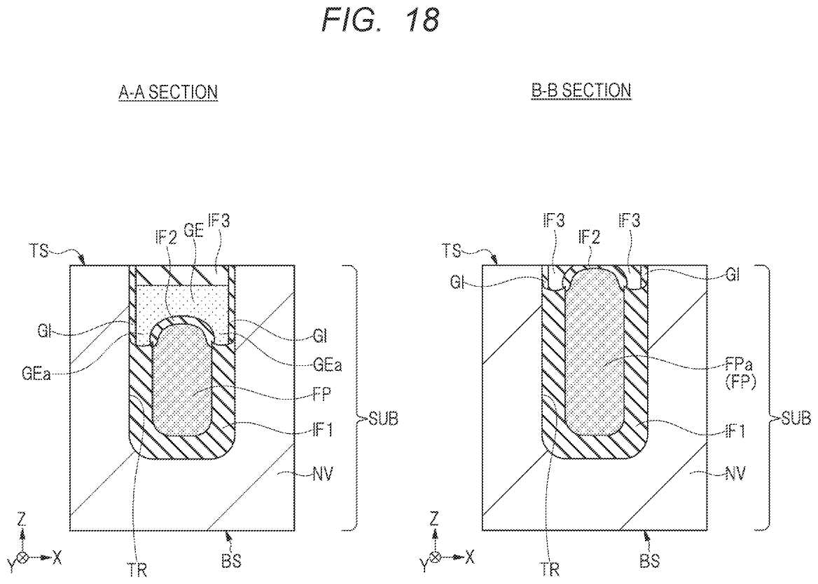

Next, as shown in FIG. 18, anisotropic etching is performed on the insulating film IF3. As a result, the insulating film IF3 and the gate insulating film GI on the upper surface TS of the semiconductor substrate SUB are removed. Furthermore, as shown in the A-A cross-section of FIG. 18, the insulating film IF3 is left on the gate electrode GE so as to contact the gate insulating film GI. Also, as shown in the B-B cross-section of FIG. 18, the insulating film IF3 is left on the insulating films IF2 and IF1 so as to contact the gate insulating film GI.

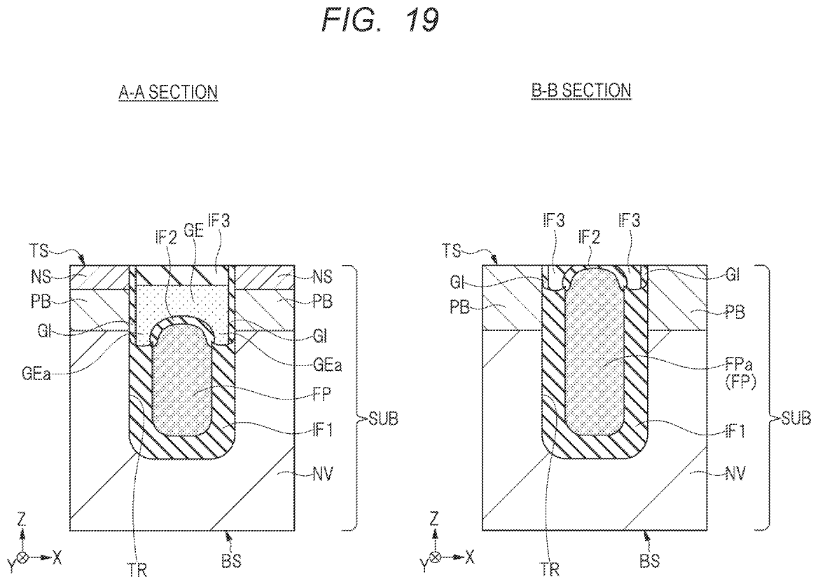

Next, as shown in FIG. 19, by introducing boron (B) for example, using photolithography and ion implantation techniques, a p-type body region PB is selectively formed in the semiconductor substrate SUB. The body region PB is formed to be shallower than the depth of the trench TR from the upper surface TS of the semiconductor substrate SUB.

Next, by introducing arsenic (As) for example, using photolithography and ion implantation techniques, as shown in the A-A cross-section of FIG. 19, an n-type source region NS is selectively formed within the body region PB of the cell region CR. Note that, as shown in the B-B cross-section of FIG. 19, no source region NS is formed in the body region PB adjacent to the lead-out portion FPa. Subsequently, by heat-treating the semiconductor substrate SUB, the impurities contained in the source region NS and the body region PB are activated.

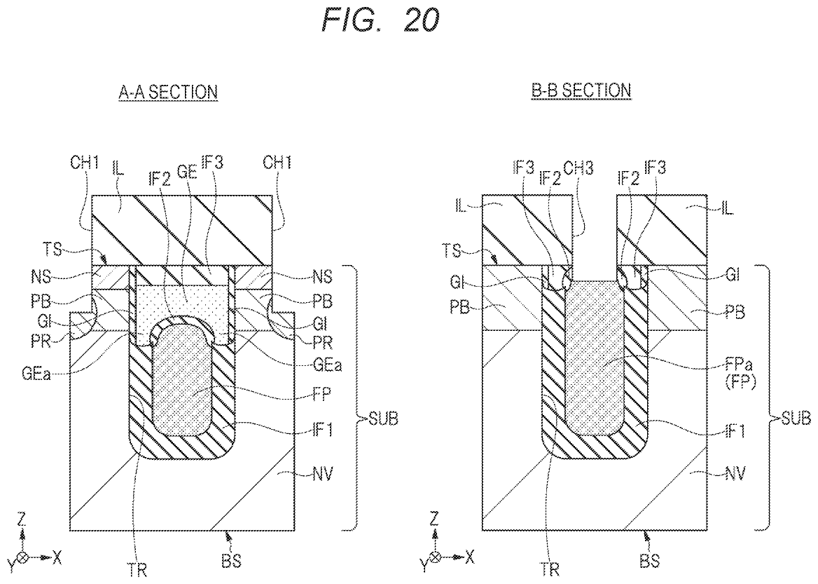

Next, as shown in FIG. 20, an interlayer insulating film IL is formed on the upper surface TS of the semiconductor substrate SUB, for example, by CVD method, so as to cover the trench TR.

Then, holes CH1, CH2, CH3 are formed in the interlayer insulating film IL. Specifically, first, a resist pattern with a pattern that opens the semiconductor substrate SUB, where the source region NS is formed, on the interlayer insulating film IL is formed. Next, by performing anisotropic etching using the resist pattern as a mask, the hole CH1 is formed, which extends through the interlayer insulating film IL and the source region NS, and reaches the interior of the body region PB. Next, by introducing boron (B), for example, into the body region PB at the bottom of the hole CH1 using ion implantation, a p-type high concentration diffusion region PR is formed. Subsequently, the resist pattern is removed by ashing.

Next, a resist pattern with a pattern that opens on the interlayer insulating film IL, on the lead-out part FPa, and on the gate electrode GE is formed. Next, by performing anisotropic etching using the resist pattern as a mask, the hole CH3 that extends through the interlayer insulating film IL, the insulating film IF3, and the insulating film IF2 and reaches the lead-out part FPa is formed. Although not shown here, the hole CH2 is also formed in the manufacturing process that forms the hole CH3. The hole CH2 extends through the interlayer insulating film IL and the insulating film IF3 and reaches the gate electrode GE. Subsequently, the resist pattern is removed by ashing.

Note that any of the formation of the hole CH1 and the formation of the hole CH2 and the hole CH3 may be performed first.

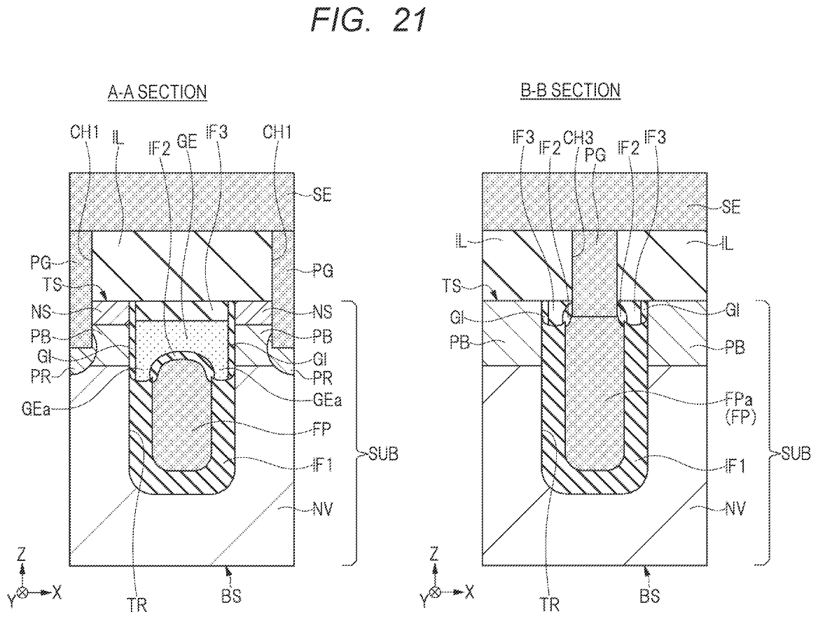

Next, as shown in FIG. 21, a plug PG is formed inside each of the holes CH1, CH2, and CH3, and a source electrode SE and a gate wiring GW are formed on the interlayer insulating film IL.

Specifically, first, a first barrier metal film is formed inside the holes CH1, CH2, CH3, and on the interlayer insulating film IL by a film formation process using sputtering or CVD. The first barrier metal film consists of, for example, a laminated film of a titanium nitride film and a titanium film. Next, a first conductive film is formed on the first barrier metal film by a film formation process using CVD. The first conductive film consists of, for example, a tungsten film. Next, the first barrier metal film and the first conductive film formed outside the holes CH1, CH2, CH3 are removed by CMP or anisotropic etching. As a result, plugs PG consisting of the first barrier metal film and the first conductive film are formed to fill the insides of the holes CH1, CH2, CH3.

Next, a second barrier metal film is formed on the interlayer insulating film IL by sputtering. The second barrier metal film consists of, for example, a titanium tungsten film. Next, a second conductive film is formed on the second barrier metal film by sputtering. The second conductive film is, for example, an aluminum alloy film with copper or silicon added. Next, the source electrode SE and the gate wiring GW are formed by patterning the second barrier metal film and the second conductive film.

Next, although not shown here, a protective film made of, for example, a polyimide film is formed on the source electrode SE and the gate wiring GW, for example, by a coating method. By forming openings in parts of the protective film, areas that become the source pad SP and the gate pad GP in the source electrode SE and the gate wiring GW are exposed.

Subsequently, through the following manufacturing processes, the structure shown in FIG. 5 is obtained. First, if necessary, the lower surface BS of the semiconductor substrate SUB is polished.

Next, an n-type drain region ND is formed on the lower surface BS of the semiconductor substrate SUB by introducing, for example, arsenic (As) by ion implantation. Note that if the semiconductor substrate SUB is composed of a laminate of an n-type silicon substrate and an n-type semiconductor layer, the aforementioned formation of the drain region ND by ion implantation can be omitted because the high-concentration n-type silicon substrate constitutes the drain region ND. Next, a drain electrode DE is formed on the lower surface BS of the semiconductor substrate SUB by sputtering.

### MODIFIED EXAMPLE

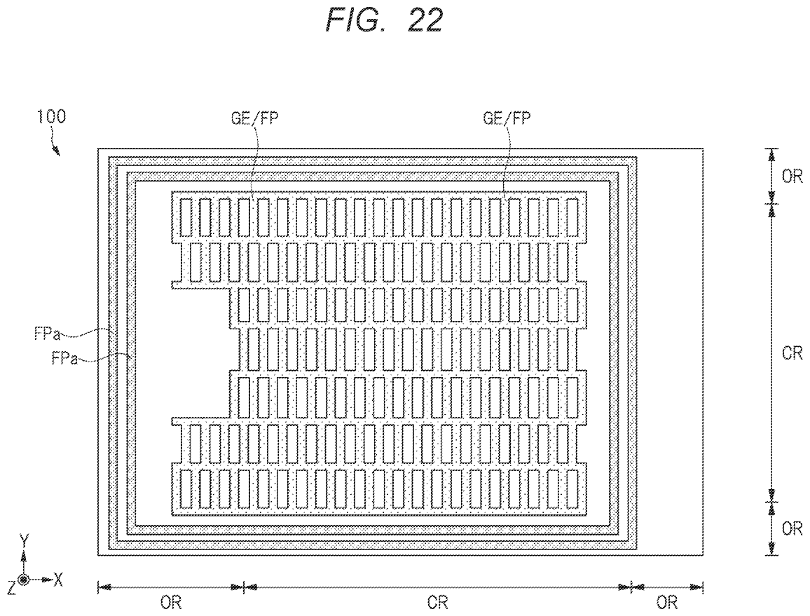

The following describes the semiconductor device 100 in a modified example of the first embodiment, using FIG. 22.

In the first embodiment, multiple trenches TR in the cell region CR extend in the Y direction, respectively, forming stripe shapes. In the modified example, as shown in FIG. 22, there are sections where multiple trenches TR extend in the X direction, and the multiple trenches TR are interconnected, forming a mesh. The technology disclosed in the first embodiment can also be applied to the structure of the trenches TR in the modified example.

### SECOND EMBODIMENT

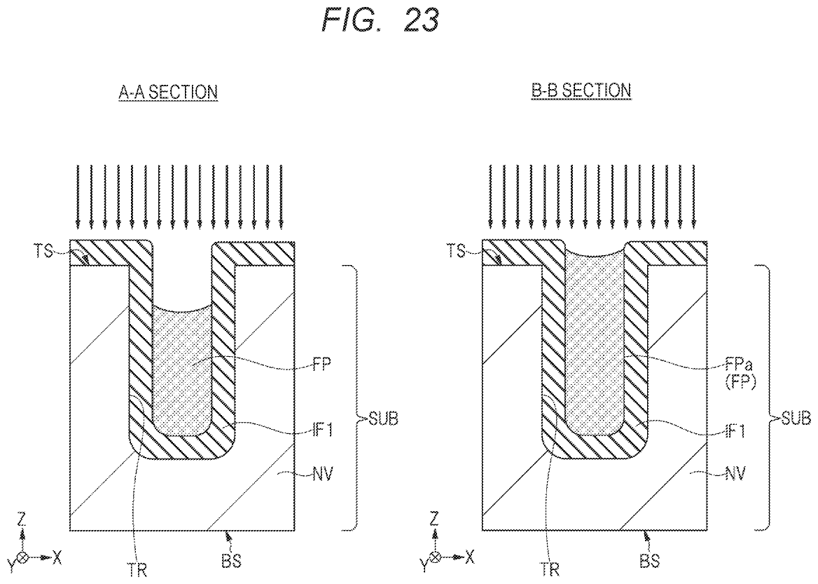

The following describes the semiconductor device 100 in the second embodiment, using FIG. 23. Note that, in the following description, differences from the first embodiment will be mainly described, and the description of overlapping points with the first embodiment will be omitted.

In the second embodiment, an ion implantation process is added between the manufacturing process of FIG. 9 and that of FIG. 10. After forming the field plate electrode FP, including the lead-out part FPa, in FIG. 9, n-type impurities such as arsenic (As) or phosphorus (P) are introduced into the field plate electrode FP, including the lead-out part FPa, by ion implantation, as shown in FIG. 23. As a result, the impurity concentration of the n-type polycrystalline silicon film constituting the field plate electrode FP becomes higher compared to the configuration of the first embodiment.

Subsequently, the thermal oxidation process of FIG. 10 is performed. Since the impurity concentration of the field plate electrode FP in the second embodiment is higher than that in the first embodiment, the effect of enhanced oxidation becomes greater. Therefore, even when performing the thermal oxidation process under the same conditions as in the first embodiment, the thickness of the silicon oxide film OX1 can be further increased.

Therefore, since the position of the starting point 10 can be made even higher, it is possible to reduce the depth of the space surrounded by the insulating films IF1, IF2, and the gate insulating film GI around the lead-out part FPa. Furthermore, since the top of the field plate electrode FP can be further rounded and the width of the top of the field plate electrode FP can be made narrower, the opening width of the aforementioned space can be further widened. In other words, according to the second embodiment, it becomes easier to further suppress the generation of residue RS.

In the second embodiment, since the effect of enhanced oxidation is utilized, replacing the thermal oxidation process of FIG. 10 with a wet etching process can achieve a higher effect.

### THIRD EMBODIMENT

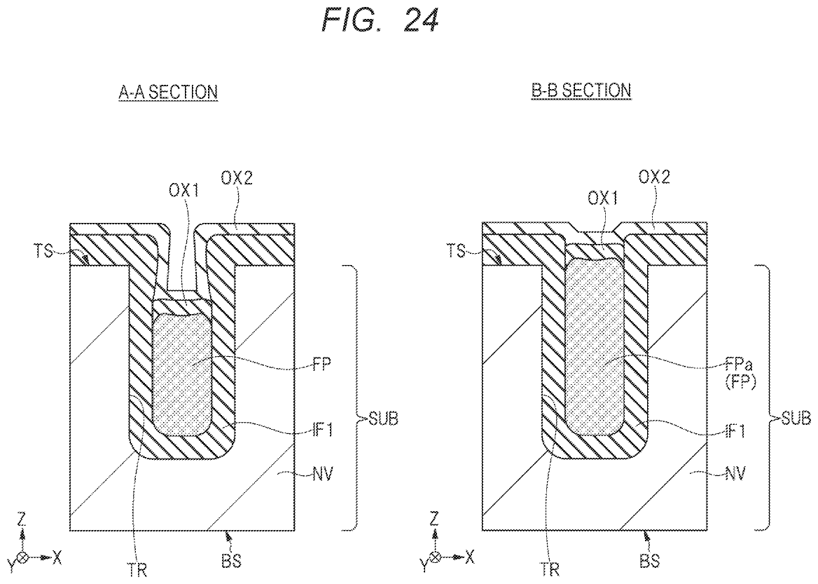

The following describes the semiconductor device 100 in the third embodiment, using FIG. 24. Note that, in the following description, differences from the first embodiment will be mainly described, and the description of overlapping points with the first embodiment will be omitted.

In the third embodiment, after performing the thermal oxidation process of FIG. 10, as shown in FIG. 24, a further silicon oxide film OX2 is formed on the insulating film IF1 and the silicon oxide film OX1, for example, by a film formation process using CVD. As shown in the A-A cross-section of FIG. 24, the silicon oxide film OX2 is formed so as not to completely fill the interior of the trench TR.

By forming the silicon oxide film OX2, the step between the insulating film IF1 on the upper surface TS of the semiconductor substrate SUB and the silicon oxide film OX1 is mitigated. By performing isotropic etching in a state in which the upper surfaces of these films are like flat surfaces as possible, after the manufacturing process of FIG. 13, it becomes easier to form the shape of the upper surface of the insulating film IF1 into a curved surface. Therefore, it becomes easier to mitigate the electric field concentration at the protrusion point 20 (near the insulating film IF1) in the examined example 1, and further secure the insulation withstand voltage between the gate electrode GE and the field plate electrode FP.

Furthermore, since the position of the starting point 10 can be raised further, it is possible to reduce the depth of the space surrounded by the insulating films IF1, IF2, and the gate insulating film GI around the lead-out part FPa. That is, according to the third embodiment, it becomes even easier to suppress the generation of residue RS.

The silicon oxide film OX2 is removed together with the silicon oxide film OX1 during the isotropic etching process of FIG. 11. If the manufacturing processes of FIGS. 11 and 12 are omitted, the silicon oxide film OX2 is removed together with the silicon oxide film OX1 during the isotropic etching process of FIG. 13.

Note that the technology of the third embodiment may be applied in combination with the technology of the second embodiment.

### FOURTH EMBODIMENT

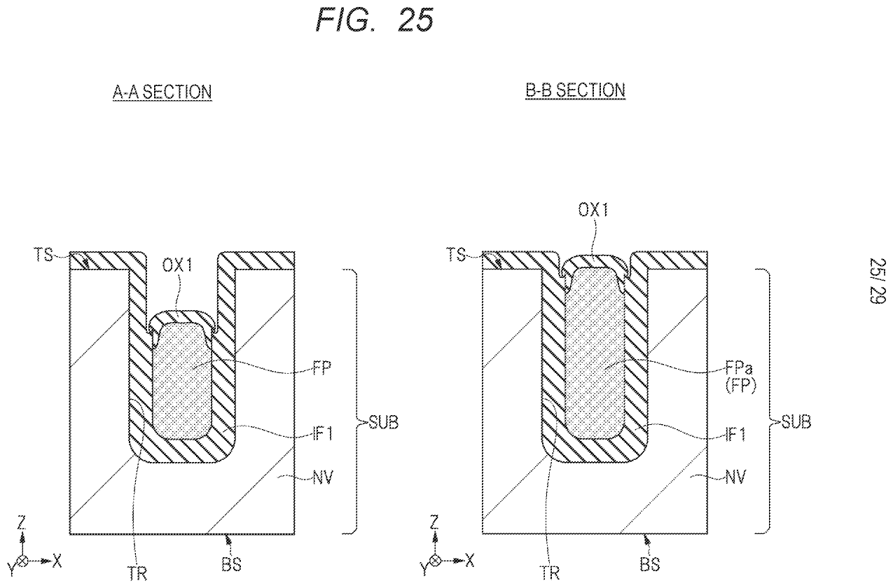

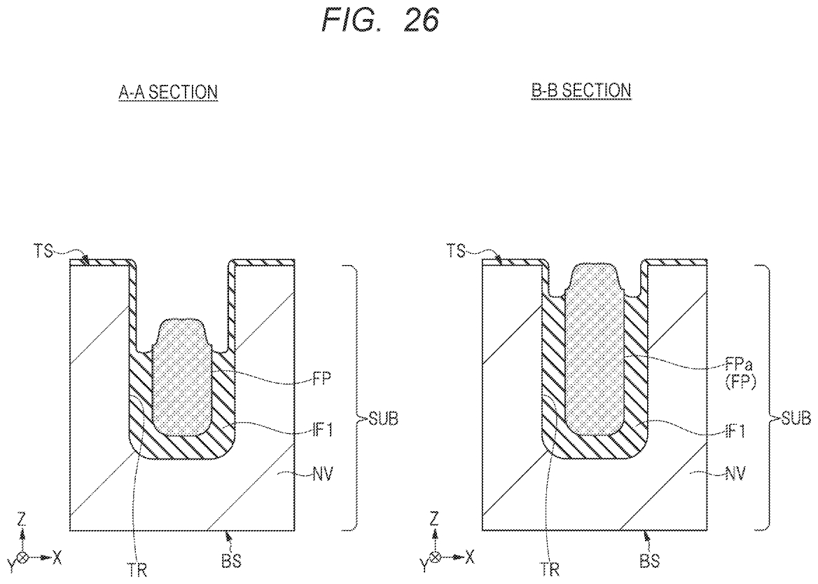

The semiconductor device 100 in the fourth embodiment will be described below using FIGS. 25 and 26. Note that, in the following description, differences from the first embodiment will be mainly described, and the description of overlapping points with the first embodiment will be omitted.

In the fourth embodiment, before the chemical dry etching process of FIG. 12, the thermal oxidation process of FIG. 10 and the isotropic etching process of FIG. 11 are repeated multiple times. After the isotropic etching process of FIG. 11, as shown in FIG. 25, the silicon oxide film OX1 is formed again on the upper surface of the field plate electrode FP by the thermal oxidation process under the same condition as FIG. 10. Furthermore, this thermal oxidation process also increases the thickness of the thinned insulating film IF1.

Next, as shown in FIG. 26, by performing the isotropic etching process under the same condition as FIG. 11, the silicon oxide film OX1 is removed, the thickness of the insulating film IF1 is reduced, and the upper part of the field plate electrode FP is exposed from the insulating film IF1.

By forming the silicon oxide film OX1 again, it is possible to further round the upper part of the field plate electrode FP and narrow the width of the upper part of the field plate electrode

FP. This allows for further widening of the opening width of the space surrounded by the insulating films IF1, IF2, and the gate insulating film GI around the lead-out part FPa. That is, according to the fourth embodiment, it becomes even easier to suppress the generation of residue RS.

Note that, if the manufacturing processes of FIGS. 11 and 12 are omitted, the thermal oxidation process of FIG. 10 and the isotropic etching process of FIG. 13 are repeated multiple times. Furthermore, the technology of the fourth embodiment may be applied in combination with the technologies of the second and third embodiments.

Thus, although the present invention has been specifically described based on the embodiments, the present invention is not limited to these embodiments and can be variously modified without departing from the gist thereof.

What is claimed is:

1. A method of manufacturing a semiconductor device comprising:
(a) providing a semiconductor substrate of a first conductivity type having an upper surface and a lower surface;
(b) after (a), forming a trench in the semiconductor substrate so as to reach a predetermined depth from the upper surface of the semiconductor substrate toward the lower surface of the semiconductor substrate;
(c) after (b), forming a first insulating film on the upper surface of the semiconductor substrate and inside the trench;
(d) after (c), forming a first conductive film on the first insulating film so as to fill the inside of the trench;
(e) after (d), removing the first conductive film located outside the trench to form the first conductive film remaining inside the trench as a field plate electrode;
(f) after (e), so that a part of the field plate electrode remains as a lead-out part, selectively retracting the other part of the field plate electrode toward the bottom of the trench;
(g) after (f), forming a first silicon oxide film on the upper surface of the field plate electrode by thermal oxidation;
(h) after (g), removing the first insulating film located on the upper surface of the semiconductor substrate and the first silicon oxide film, and retracting the first insulating film located inside the trench toward the bottom of the trench so that the position of the upper surface of the first insulating film located inside the trench is lower than the position of the upper surface of the field plate electrode in cross-sectional view;
(i) after (h), forming a gate insulating film inside the trench on the first insulating film and forming a second insulating film so as to cover the field plate electrode exposed from the first insulating film;
(j) after (i), forming a second conductive film on the gate insulating film, the second insulating film, and the first insulating film to fill the inside of the trench; and
(k) after (j), removing the second conductive film located outside the trench to form the second conductive film remaining inside the trench on the field plate electrode as a gate electrode,
wherein the second conductive film formed on the first insulating film and the second insulating film in contact with the lead-out part by (j) is removed by (k).

2. The method of manufacturing a semiconductor device according to claim 1, wherein the thermal oxidation in (g) process is performed using water vapor under a conditions of 850 degrees Celsius or higher and 950 degrees Celsius or lower.

3. The method of manufacturing a semiconductor device according to claim 2, wherein (h) includes:
(h1) after (g), removing the first silicon oxide film, thinning the thickness of the first insulating film, and exposing the upper part of the field plate electrode from the first insulating film;
(h2) after (h1), performing isotropic etching treatment on the upper part of the field plate electrode exposed from the first insulating film; and
(h3) after (h2), removing the first insulating film located on the upper surface of the semiconductor substrate, and retreating the first insulating film located inside the trench toward the bottom of the trench so that the position of the upper surface of the first insulating film located inside the trench is lower than the position of the upper surface of the field plate electrode in cross-sectional view.

4. The method of manufacturing a semiconductor device according to claim 3, wherein the first insulating film is a silicon oxide film, and (h1) and (h3) are performed by isotropic etching treatment using a solution containing hydrofluoric acid.

5. The method of manufacturing a semiconductor device according to claim 4, wherein the field plate electrode is made of polycrystalline silicon film, and the isotropic etching treatment in (h2) is a chemical dry etching treatment using CF₄ gas.

6. The method of manufacturing a semiconductor device according to claim 5, wherein the upper part of the field plate electrode is rounded by the chemical dry etching treatment.

7. The method of manufacturing a semiconductor device according to claim 3, further comprising:
(l) between (f) and (g), introducing an impurity of the first conductivity type into the field plate electrode by ion implantation.

8. The method of manufacturing a semiconductor device according to claim 3, further comprising:
(m) between (g) and (h1), forming a second silicon oxide film on the first insulating film and the first silicon oxide film by a film formation process using CVD,
wherein the second silicon oxide film is removed together with the first silicon oxide film in (h1).

9. The method of manufacturing a semiconductor device according to claim 3, wherein, after repeating (g) and the (h1) multiple times, (h2) is performed.

10. The method of manufacturing a semiconductor device according to claim 2, further comprising:
(n) between (f) and (g), introducing an impurity of the first conductivity type into the field plate electrode by ion implantation.

11. The method of manufacturing a semiconductor device according to claim 1, further comprising:
(o) between (g) and (h), forming a second silicon oxide film on the first insulating film and the first silicon oxide film by film formation using a CVD method,
wherein the second silicon oxide film is removed together with the first silicon oxide film in (h).

12. The method of manufacturing a semiconductor device according to claim 1, wherein, after repeating (g) and (h) multiple times, (i) is performed.

13. The method of manufacturing a semiconductor device according to claim 1, wherein the thermal oxidation of (g) is performed using oxygen gas under a condition of at least 1000 degrees Celsius and not more than 1200 degrees Celsius.

14. The method of manufacturing a semiconductor device according to claim 1, wherein (e) includes:
(e1) polishing the first conductive film located outside the trench; and
(e2) after (e1), retreating the position of the upper surface of the first conductive film inside the trench toward the bottom of the trench by anisotropic etching.
